(19) United States
(12) Patent Application Publication
(10) Pub. No.: US 2025/0304827 A1
(43) Pub. Date: Oct. 2, 2025

(54) SLURRY COMPOSITION, METHOD FOR STORING SLURRY COMPOSITION, METHOD FOR PRODUCING CMP SLURRY, AND POLISHING METHOD

(71) Applicant: FUJIMI INCORPORATED, Aichi (JP)

(72) Inventors: Atsushi Tsuzuki, Aichi (JP); Masashi Abe, Aichi (JP)

(21) Appl. No.: 19/090,698

(22) Filed: Mar. 26, 2025

(30) Foreign Application Priority Data
Mar. 28, 2024 (JP) 2024-054846

(51) Int. Cl. C09G 1/02; C09K 3/14; H01L 21/306; H01L 21/3105; H01L 21/321

(52) U.S. Cl. CPC C09G 1/02; C09K 3/1436; H01L 21/30625; H01L 21/31053; H01L 21/3212

(57) ABSTRACT

There are provided a slurry composition suppressed in a change in physical properties and capable of being imparted with stable polishing performance even after stored over a long period of time, a method for storing the slurry composition, a method for producing a CMP slurry, and a polishing method.

A slurry composition contains: colloidal silica; and an acidic compound, in which the pH is less than 7, the colloidal silica has a surface modified by an aminosilane coupling agent, and, when the average secondary particle diameter of the colloidal silica is set to dₚ [mm], the ratio of the volume of the colloidal silica to the volume of the slurry composition is set to F, and the ratio of circumference of circle to its diameter is set to π, the average distance between particle surfaces h of the colloidal silica represented by Equation (1) is less than 65 nm,

$$[ Math . 1 ]$$

$$h = {d}_{p} \{ \sqrt{( \frac{3}{3 π f} + \frac{5}{6} )} - 1 \} . \qquad ( 1 )$$

### TECHNICAL FIELD

The present invention relates to a slurry composition, a method for storing a slurry composition, a method for producing a CMP slurry, and a polishing method.

### BACKGROUND ART

In recent years, with the multilayer wiring on the surface of a semiconductor substrate, a so-called chemical mechanical polishing (CMP) art of polishing and flattening a semiconductor substrate is utilized in producing a device.

The CMP is a method for flattening the surfaces of objects to be polished (polishing targets), such as a semiconductor substrate, using a slurry containing abrasives of silica, alumina, ceria, and the like, an anticorrosive agent, a surfactant, and the like. The objects to be polished are, for example, silicon, polysilicon, a silicon oxide film (silicon oxide), silicon nitride, wiring and plugs containing metals and the like.

A change in physical properties of the CMP slurry from production to use poses problems, such as the occurrence of defective polishing. Therefore, the CMP slurry has been demanded to have stable physical properties and polishing performance from production to use for polishing.

### SUMMARY

### Technical Problem

A CMP slurry containing cationized colloidal silica has posed such a problem that the physical properties of the slurry are changed from production to use, resulting in a decrease in polishing performance because the stability of the cationized colloidal silica as the abrasives is not high.

The present invention has been made in view of the above-described circumstances. It is an object of the present invention to provide a slurry composition capable of producing a CMP slurry suppressed in a change in physical properties and having stable polishing performance even when the CMP slurry is stored over a long period of time, a method for storing the slurry composition, a method for preparing the CMP slurry, and a polishing method.

### Solution to Problem

The present inventors have conducted extensive studies in view of the above-described object. As a result, the present inventors have found that a slurry composition containing: colloidal silica; and an acidic compound and having a pH of less than 7, in which the colloidal silica has a surface modified by an aminosilane coupling agent and the average distance between particle surfaces of the colloidal silica represented by Equation (1) below is less than 65 nm, is suppressed in a change in physical properties and has stable polishing performance even after long-term storage. In Equation (1), h [nm] represents the average distance between particle surfaces of the colloidal silica, dₚ [nm] represents the average secondary particle diameter of the colloidal silica, F represents the ratio of the volume of the colloidal silica to the volume of the slurry composition, and π represents the ratio of circumference of circle to its diameter.

$$[ Math . 1 ]$$

$$h = {d}_{p} \{ \sqrt{( \frac{1}{3 π F} + \frac{5}{6} )} - 1 \} \qquad ( 1 )$$

### Advantageous Effects of Invention

One aspect of the present invention can provide a slurry composition capable of producing a CMP slurry suppressed in a change in physical properties and having stable polishing performance even when the CMP slurry is stored over a long period of time, a method for storing the slurry composition, a method for producing the CMP slurry, and a polishing method.

### BRIEF DESCRIPTION OF DRAWINGS

FIG. 1 is a graph showing a zeta potential change in a CMP slurry containing a slurry composition stored at 80° C. for 7 days with a CMP slurry containing a slurry composition immediately after production as a reference to the mass concentration of colloidal silica in the slurry composition in one embodiment of the present invention; and

FIG. 2 is a graph showing a zeta potential change in a CMP slurry containing a slurry composition stored at 80° C. for 7 days with a CMP slurry containing a slurry composition immediately after production as a reference to the average distance between particle surfaces of colloidal silica in the slurry composition in one embodiment of the present invention.

### DESCRIPTION OF EMBODIMENTS

Embodiments of the present invention are described in detail. A slurry composition according to the embodiment of the present invention contains colloidal silica and an acidic compound, and the slurry composition has a pH of less than 7. The colloidal silica has a surface modified by an aminosilane coupling agent, and the average distance between particle surfaces h of the colloidal silica represented by Equation (1) below is less than 65 nm. Herein, dₚ [nm] represents the average secondary particle diameter of the colloidal silica, F represents the ratio of the volume of the colloidal silica to the volume of the slurry composition, and π represents the ratio of circumference of circle to its diameter.

$$[ Math . 2 ]$$

$$h = {d}_{p} \{ \sqrt{( \frac{1}{3 π F} + \frac{5}{6} )} - 1 \} \qquad ( 1 )$$

The slurry composition according to this embodiment may also be a CMP slurry for storage. This is because a change in physical properties as the CMP slurry with the passage of time is small and a change in polishing performance can be suppressed, and therefore the CMP slurry is suitable for long-term storage.

Hereinafter, the slurry composition according to this embodiment is described in detail. The embodiment described below gives one example of the present invention, and the present invention is not limited to the embodiment. The embodiment described below can be variously altered or improved, and such altered or improved aspects can also be included in the present invention.

### <Abrasives>

The slurry composition according to this embodiment contains colloidal silica as abrasives. A colloidal silica production method includes a soda silicate method and a sol-gel method. Any colloidal silica produced by any production method is suitably used as the abrasives of the present invention. However, colloidal silica produced by the sol-gel method capable of producing high-purity colloidal silica is preferable.

### (Surface Modification)

The colloidal silica is surface-modified by an aminosilane coupling agent. By the surface modification, the aminosilane coupling agent is immobilized and cationized on the surface of the colloidal silica. In this specification, the colloidal silica subjected to the cationization is referred to as “cationized colloidal silica”.

A method for producing the colloidal silica having an amino group includes a method for immobilizing a silane coupling agent having an amino group, such as aminoethyltrimethoxysilane, on the surface of silica particles as described in JP 2005-162533 A. In this specification, the silane coupling agent having an amino group is referred to as “aminosilane coupling agent”.

The aminosilane coupling agent includes, for example, bis(2-hydroxyethyl)-3-aminopropyltrialkoxysilane, diethylaminomethyltrialkoxysilane, (N,N-diethyl-3-aminopropyl)trialkoxysilane, 3-(N-styrylmethyl-2-aminoethylamino)propyltrialkoxysilane, aminopropyltrialkoxysilane, trialkoxysilylpropyl-N,N,N-trimethylammonium, bis(methyldialkoxysilylpropyl)-N-methylamine, bis(trialkoxysilylpropyl)urea, bis(3-(trialkoxysilyl)propyl)-ethylenediamine, bis(trialkoxysilylpropyl)amine, 3-aminopropyltrialkoxysilane, N-(2-aminoethyl)-3-aminopropylmethyldialkoxysilane, N-(2-aminoethyl)-3-aminopropyltrialkoxysilane, 3-aminopropylmethyldialkoxysilane, 3-aminopropyltrialkoxysilane, (N-trialkoxysilylpropyl) polyethyleneimine, trialkoxysilylpropyldiethylenetriamine, N-phenyl-3-aminopropyltrialkoxysilane, 4-aminobutyltrialkoxysilane, and the like. In this embodiment, one type of the aminosilane coupling agents modifying the surface of the colloidal silica may be used alone or two or more types thereof may be used in combination.

The aminosilane coupling agent can be added to the colloidal silica without being diluted or diluted with a hydrophilic organic solvent or pure water. Dilution with a hydrophilic organic solvent or pure water can suppress the formation of aggregates.

The hydrophilic organic solvents include, but are not particularly limited, lower alcohols, such as methanol, ethanol, isopropanol, and butanol.

The usage amount of the aminosilane coupling agent is not particularly limited, and may be such a usage amount that the mass concentration of the aminosilane coupling agent in the slurry composition is 1/1000-fold or more, 1/500-fold or more, and 1/200-fold or more of the mass concentration of the colloidal silica in the slurry composition. Within such ranges, the degree of denaturation of the colloidal silica increases, making it easy to obtain cationized colloidal silica that can be stably dispersed over a long period of time. The usage amount may be such a usage amount that the mass concentration of the aminosilane coupling agent in the slurry composition is equal to or smaller than the mass concentration of the colloidal silica in the slurry composition, or ½-fold or less or 1/10-fold or less of the mass concentration of the colloidal silica in the slurry composition. Within such ranges, problems, such as an increase in secondary particle diameter of the colloidal silica, the formation of aggregates, and gelation, hardly occur.

The dispersion stability of the colloidal silica can be evaluated by measuring the zeta potential of the colloidal silica. This is because, when the absolute value of the zeta potential increases, the electrical repulsion between particles becomes stronger, increasing the stability of the particles, and, when the absolute value of the zeta potential approaches zero, the particles are likely to be aggregated. Common colloidal silica has the zeta potential value close to zero under acidic conditions, and therefore particles of the colloidal silica do not electrically repel each other, and thus are likely to be aggregated under acidic conditions. In contrast thereto, the cationized colloidal silica has a positive zeta potential, and therefore particles of the cationized colloidal silica strongly repel each other, and thus hardly aggregate even under acidic conditions. As a result, the storage stability of the slurry composition is improved.

### (Average Distance Between Particle Surfaces of Colloidal Silica)

The average distance between particle surfaces (h) of the colloidal silica can be determined by Equation (1) below. In Equation (1), h [nm] represents the average distance between particle surfaces of the colloidal silica, dₚ [mm] represents the average secondary particle diameter of the colloidal silica, F represents the ratio of the volume of the colloidal silica to the volume of the slurry composition, and π represents the ratio of circumference of circle to its diameter.

$$[ Math . 3 ]$$

$$h = {d}_{p} \{ \sqrt{( \frac{1}{3 π F} + \frac{5}{6} )} - 1 \} \qquad ( 1 )$$

The average distance between particle surfaces (h) of the cationized colloidal silica contained in the slurry composition may be less than 65 nm, may be less than 60 nm, or may be less than 55 nm. When the average distance between particle surfaces falls within such ranges, the average distance between particle surfaces of the cationized colloidal silica contained in the slurry composition is very short as compared with that of the CMP slurry having the average distance between particle surfaces outside the ranges above. Therefore, the aminosilane coupling agent modified on the surface of the colloidal silica contained in the slurry composition is hardly detached even when time has passed since the production, making it easy to suppress a decrease in zeta potential.

The average distance between particle surfaces of the cationized colloidal silica can be appropriately controlled by adjusting the average secondary particle diameter and the volume ratio of the colloidal silica. The larger the average secondary particle diameter of the colloidal silica, the larger the average distance between particle surfaces (h) tends to be. The larger the volume ratio of the colloidal silica, the smaller the average distance between particle surfaces (h) tends to be.

### (Average Secondary Particle Diameter)

The average secondary particle diameter of the cationized colloidal silica may be 90 nm or less, may be 80 nm or less, may be 70 nm or less, may be 60 nm or less, or may be 50 nm or less. The average secondary particle diameter of the surface-modified cationized colloidal silica may be 30 nm or more and may be 40 nm or more. Within such ranges, when the slurry composition is diluted and used as the CMP slurry, the polishing removal rate of an object to be polished is improved. In addition, the occurrence of surface defects on the surface of the object to be polished after polishing with the CMP slurry can be further suppressed. The secondary particles refer to particles formed by the association of colloidal silica (primary particles), on the surface of which an organic acid is immobilized, in the slurry composition. The average secondary particle diameter of the secondary particles can be measured by dynamic light scattering, for example.

The average secondary particle diameter of the cationized colloidal silica can be appropriately controlled by the selection of a method for producing cationized colloidal silica, for example.

### (Mass Concentration of Colloidal Silica)

The mass concentration of the colloidal silica in the slurry composition may be 5% by mass or more and may be 5.4% by mass or more. The mass concentration of the colloidal silica may be 20% by mass or less and may be 18% by mass or less. When the mass concentration of the colloidal silica is 5% by mass or more, the slurry composition capable of maintaining stable physical properties and polishing performance can be obtained even when stored over a long period of time.

### <Acidic Compound>

The pH of the slurry composition according to this embodiment may be less than 7, may be less than 5, and may be less than 3. The pH of the slurry composition according to this embodiment may be 1 or more and 2 or more. Within such ranges, the zeta potential of the surface-modified cationized colloidal silica is likely to be a positive value and the cationized colloidal silica is hardly aggregated in the slurry, and therefore the storage property is improved.

The pH of the slurry composition according to this embodiment can be adjusted by adding an acidic compound. Specific examples of the acidic compound include inorganics acid and organic acids.

Specific examples of the inorganic acids include sulfuric acid, nitric acid, boric acid, carbonic acid, hypophosphorous acid, phosphorous acid, phosphoric acid, and the like. As the acidic compounds, inorganic acids may be used, sulfuric acid and nitric acid may be used, or nitric acid may be used.

The organic acids include carboxylic acids and organic sulfuric acids. Specific examples of the carboxylic acids include formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, and the like. Specific examples of the organic sulfuric acids include methanesulfonic acid, ethanesulfonic acid, isethionic acid, and the like. One type of these acids may be used alone or two or more types thereof may be used in combination. These acids may be contained in the slurry composition as additives for improving the polishing removal rate.

### <Water-Soluble Polymer>

The slurry composition according to the embodiment of the present invention may contain a water-soluble polymer. The inclusion of the water-soluble polymer can make it easy to suppress a change in zeta potential of the slurry composition.

Specific examples of the water-soluble polymer include polyvinyl alcohol (PVA), polyvinylpyrrolidone, polyethylene glycol (PEG), polypropylene glycol (PPG), polybutylene glycol, a copolymer of oxyethylene (EO) and oxypropylene (PO), methyl cellulose, hydroxyethyl cellulose, dextrin, pullulan, and the like. One type of the water-soluble polymers may be used alone or two or more types thereof may be used in combination. Among the water-soluble polymers, nonionic polymers are preferable because the nonionic polymers do not affect the zeta potential of the slurry composition.

### <Oxidant>

The slurry composition according to the embodiment of the present invention may contain an oxidant. Specific examples of the oxidant include hydrogen peroxide, peracetic acid, percarbonate, urea peroxide, perchloric acid, persulfate, and the like. One type of the oxidants may be used alone or two or more types thereof may be used in combination.

### <Antifungal Agent, Preservative>

The slurry composition may contain an antifungal agent and a preservative. Specific examples of the antifungal agent and the preservative include isothiazoline preservatives (e.g., 2-methyl-4-isothiazolin-3-one, 5-chloro-2-methyl-4-isothiazolin-3-one), para-hydroxybenzoate, phenoxyethanol, and the like. One type of the antifungal agents and the preservatives may be used alone or two or more types thereof may be used in combination.

### <Liquid Medium>

The slurry composition according to the embodiment of the present invention may contain a liquid medium. The liquid medium functions as a dispersion medium or a solvent for dispersing or dissolving, respectively, the components (colloidal silica, aminosilane coupling agent, acidic compound, and the like) of the slurry composition. Examples of the liquid medium include water and organic solvents. One type of the liquid media can be used alone or two or more types thereof can be used as a mixture, and the liquid media preferably contain water. However, from the viewpoint of preventing the inhibition of the action of each component, water containing as little impurities as possible is preferably used. Specifically, pure water or ultrapure water obtained by removing impurity ions with an ion exchange resin, and then removing contaminants through a filter, or distilled water is preferable.

### <Method for Producing Slurry Composition>

A method for producing the slurry composition according to this embodiment is not particularly limited, and the slurry composition can be produced by stirring and mixing the colloidal silica surface-modified by the aminosilane coupling agent, the acidic compound, and, as required, various additives (e.g., water-soluble polymer, oxidant, antifungal agent, and the like) in the liquid medium, such as water. The temperature in the mixing is not particularly limited, and is preferably 10° C. or more and 40° C. or less, for example, and heating may be performed to improve the dissolution rate. The mixing time is also not particularly limited.

### <Method for Storing Slurry Composition>

A method for storing the slurry composition according to another embodiment of the present invention includes preparing a slurry composition containing the colloidal silica having a surface modified by the aminosilane coupling agent and the acidic compound and having a pH of less than 7 such that the average distance between particle surfaces (h) of the colloidal silica represented by Expression (1) is less than 65 nm and storing the prepared slurry composition. Herein, h [nm] represents the average distance between particle surfaces of the colloidal silica, dₚ [mm] represents the average secondary particle diameter of the colloidal silica contained in the slurry composition, F represents the ratio of the volume of the colloidal silica to the volume of the slurry composition, and π represents the ratio of circumference of circle to its diameter. The “preparing” means selecting the average secondary particle diameter and the volume ratio of the colloidal silica and producing a slurry composition having a desired average distance between particle surfaces.

$$[ Math . 4 ]$$

$$h = {d}_{p} \{ \sqrt{( \frac{1}{3 π F} + \frac{5}{6} )} - 1 \} \qquad ( 1 )$$

The slurry composition in the method for storing a slurry composition according to this embodiment is the same composition as the slurry composition according the present invention described above.

According to a method for storing the slurry composition of according to this embodiment, the slurry composition is stored in a high concentration state where a change in physical properties hardly occurs. Therefore, the CMP slurry obtained by diluting the slurry composition in use can be imparted with excellent polishing performance as compared with the polishing performance in a case of being stored in a common low-concentration CMP slurry state.

### <Method for Producing CMP Slurry>

A method for producing a CMP slurry according to another embodiment of the present invention includes preparing a slurry composition containing colloidal silica having a surface modified by the aminosilane coupling agent and the acidic compound and having a pH of less than 7 such that the average distance between particle surfaces (h) of the colloidal silica represented by Expression (1) is less than 65 nm, storing the prepared slurry composition, and diluting the stored slurry composition with the liquid medium to obtain a CMP slurry. Herein, h [nm] represents the average distance between particle surfaces of the colloidal silica, dₚ [nm] represents the average secondary particle diameter of the colloidal silica contained in the slurry composition, F represents the ratio of the volume of the colloidal silica to the volume of the slurry composition, and π represents the ratio of circumference of circle to its diameter.

$$[ Math . 5 ]$$

$$h = {d}_{p} \{ \sqrt{( \frac{1}{3 π F} + \frac{5}{6} )} - 1 \} \qquad ( 1 )$$

The slurry composition in the method for producing a CMP slurry according to this embodiment is the same composition as the slurry composition according to the present invention described above.

### <Polishing Method>

A polishing method according to this embodiment includes diluting the slurry composition according to the present invention with the liquid medium to obtain a CMP slurry and polishing an object to be polished provided on a substrate using the obtained CMP slurry.

The liquid medium used for the dilution includes water and organic solvents. One type of the liquid media can be used alone or two or more types thereof can be used as a mixture, and the liquid media preferably contain water. However, from the viewpoint of preventing the inhibition of the action of each component, water containing as little impurities as possible is preferably used. Specifically, pure water or ultrapure water obtained by removing impurity ions with an ion exchange resin, and then removing contaminants through a filter, or distilled water is preferable. The liquid medium used for the dilution may be the same type of liquid medium as the liquid medium used for the slurry composition according to the present invention or may be a different type of liquid medium.

In the polishing method according to this embodiment, the configuration of a polishing device is not particularly limited. For example, common polishing devices are usable which include a holder holding a substrate or the like having the object to be polished, a drive unit, such as a motor having a changeable rotation speed, and a polishing platen to which a polishing pad can be attached. As the polishing pad, common non-woven fabrics, polyurethane, porous fluororesin, and the like are usable without being particularly restricted. As the polishing pad, those subjected to grooving such that a liquid CMP slurry stays are usable.

The polishing conditions are not particularly restricted, and the rotation speed of the polishing platen is preferably 10 rpm (0.17 s⁻¹) or more and 500 rpm (8.3 s⁻¹) or less, for example. The pressure (polishing pressure) applied to the substrate having the object to be polished is preferably 0.5 psi (3.4 kPa) or more and 10 psi (68.9 kPa) or less. A method for supplying the CMP slurry to the polishing pad is also not particularly restricted, and a method for continuously supplying the CMP slurry with a pump or the like is adopted. The supply amount is not restricted, and the surface of the polishing pad is preferably constantly covered with the CMP slurry according to this embodiment.

The CMP slurry may be a one-component type or a multi-component type including a two-component type.

After the polishing, for example, the substrate is cleaned with running water, and dried by removing water droplets adhering onto the substrate with a spin dryer or the like, thereby giving the substrate having a layer containing a silicon-containing material, for example. Thus, the CMP slurry according to this embodiment is usable in application of polishing the substrate.

The surface of the object to be polished provided on a semiconductor substrate is polished using the CMP slurry according to this embodiment, whereby the surface of the semiconductor substrate is polished at high polishing removal rate, so that the polished semiconductor substrate can be produced. The semiconductor substrate includes, for example, silicon, polysilicon, a silicon oxide film (silicon oxide), silicon nitride, wiring and plugs containing metals and the like.

### EXAMPLES

The present invention is described in more detail with reference to Examples and Comparative Examples described below. However, the technical scope of the present invention is not restricted to only Examples described below. Examples described below can be variously altered or modified, and such altered or modified aspects may also be included in the present invention.

### Example 1

### <Preparation of Slurry Composition>

To a liquid concentrate of colloidal silica (20% by mass), 3-aminopropyl triethoxysilane having a concentration of 83.48 mmol/L was added as the aminosilane coupling agent, giving a surface-modified cationized colloidal silica. The average secondary particle diameter of the obtained cationized colloidal silica was 50 nm.

The above-described surface-modified cationized colloidal silica, nitric acid, and water were stirred and mixed, preparing a slurry composition having a mass concentration of the colloidal silica of 5.4% by mass (Example 1).

### <Storage of Slurry Composition and Production of CMP Slurry>

The obtained slurry composition was stored at 80° C. for 7 days. The “at 80° C. for 7 days” is equivalent to “stored at 25° C. for 317 days” according to the Arrhenius acceleration equation. Thereafter, the slurry composition after storage was diluted with water such that the mass concentration of the colloidal silica was 0.9% by mass, producing a CMP slurry.

### Examples 2 to 5, Comparative Examples 1, 2

Slurry compositions of Examples 2 to 5 and Comparative Examples 1, 2 were prepared in the same manner as in Example 1, except for changing the colloidal silica concentration of the slurry composition as shown in Table 1. Thereafter, the slurry compositions were stored at 80° C. for 7 days and diluted with water such that the mass concentration of the colloidal silica was 0.9% by mass in the same manner as in Example 1, so that CMP slurries were individually produced.

### Reference Example

The slurry composition of Example 1 was diluted with water such that the mass concentration of the colloidal silica was 0.9% by mass, producing a CMP slurry of Reference Example. Unlike Example 1, the slurry composition was not subjected to the storage at 80° C. for 7 days.

### <Calculation of Average Distance Between Particle Surfaces>

The average distance between particle surfaces of the colloidal silica in the slurry composition of each of Examples 1 to 5 and Comparative Examples 1, 2 was calculated from Equation (1) below. In Equation (1), h [nm] represents the average distance between particle surfaces of the colloidal silica, dₚ [nm] represents the average secondary particle diameter of the colloidal silica, F represents the ratio of the volume of the colloidal silica to the volume of the slurry composition, and π represents the ratio of circumference of circle to its diameter. The volume ratio F of the colloidal silica was determined by conversion from the mass concentration of the colloidal silica. The results are shown in Table 1.

$$[ Math . 6 ]$$

$$h = {d}_{p} \{ \sqrt{( \frac{1}{3 π F} + \frac{5}{6} )} - 1 \} \qquad ( 1 )$$

TABLE 1

| | Slurry composition | | | | | | | | | | | | | | |
|---|---|---|---|---|---|---|---|---|---|---|---|---|---|---|---|
| | Con- | Concent- | | Average | | Storage conditions | | | CMP slurry | | | | | | |
| | cent- | ration of | Coll- | distance | | | | Con- | | | | | Polishing removal | | |
| | ration | colloidal | oidal | between | | Storage | | version | | Zeta potential | | | rate for TEOS film | | |
| | factor | silica | silica | particle | | temp- | Storage | value | | | Decrease | | | Increase | Increase |
| | to CMP | [% by | volume | surfaces | | erature | period | [days] | | | amount* | Decrease | | amount** | rate |
| | slurry | mass] | ratio | [nm] | pH | [° C.] | [days] | (25° C.) | pH | [mV] | [mV] | rate [%] | [Å/min] | [Å/min] | [%] |
| Comp. | 3-fold | 2.7 | 0.015 | 91 | 2.5 | 80 | 7 | 317 | 2.9 | 22.4 | 14.2 | 38.8 | 77.2 | 6.7 | 9.5 |
| Ex. 1 | | | | | | | | | | | | | | | |
| Comp. | 4-fold | 3.6 | 0.020 | 74 | 2.4 | 80 | 7 | 317 | 3.0 | 24.0 | 12.7 | 34.6 | 76.2 | 5.7 | 8.1 |
| Ex. 2 | | | | | | | | | | | | | | | |
| Ex. 1 | 6-fold | 5.4 | 0.030 | 55 | 2.2 | 80 | 7 | 317 | 3.0 | 34.6 | 2.1 | 5.7 | 74.5 | 4.0 | 5.6 |
| Ex. 2 | 7-fold | 6.3 | 0.035 | 48 | 2.1 | 80 | 7 | 317 | 3.0 | 34.5 | 2.2 | 5.9 | 74.6 | 4.1 | 5.9 |
| Ex. 3 | 8-fold | 7.2 | 0.040 | 43 | 2.1 | 80 | 7 | 317 | 3.0 | 34.0 | 2.7 | 7.3 | 75.6 | 5.1 | 7.3 |
| Ex. 4 | 10-fold | 9 | 0.050 | 36 | 2.0 | 80 | 7 | 317 | 3.0 | 34.8 | 1.9 | 5.2 | 74.1 | 3.6 | 5.2 |
| Ex. 5 | 20-fold | 18 | 0.100 | 19 | 1.6 | 80 | 7 | 317 | 3.0 | 35.9 | 0.8 | 2.1 | 72.0 | 1.5 | 2.1 |
| Ref. | 6-fold | 5.4 | 0.030 | 55 | — | — | — | — | 3.0 | 36.7 | — | — | 70.5 | — | — |

*Decrease amount of zeta potential from zeta potential of Reference Example [mV]
**Increase amount of polishing removal rate from polishing removal rate for TEOS film of Reference Example [Å/min]

### <pH Measurement>

The pH of the slurry composition (liquid temperature: 25° C.) of each of Examples 1 to 5 and Comparative Examples 1, 2, and the CMP slurry (liquid temperature: 25° C.) of each of Examples 1 to 5, Comparative Examples 1, 2, and Reference Example was measured with a pH meter (product name: LAQUA (registered trademark) manufactured by Horiba, Ltd.). The results are shown in Table 1.

### <Measurement of Zeta Potential>

The zeta potential of the cationized colloidal silica in the CMP slurry of each of Examples 1 to 5 and Comparative Examples 1, 2 was measured. The zeta potential was calculated by subjecting each CMP slurry to the Zetasizer Nano manufactured by Malvern Panalytical, measuring the zeta potential by the laser Doppler method (electrophoretic light scattering measurement method) using a flow cell at a measurement temperature of 25° C., and analyzing the obtained data by the Smoluchowski equation.

The decrease amount of the zeta potential was calculated by subtracting the zeta potential of the CMP slurry of each of Examples 1 to 5 and Comparative Examples 1, 2 from the zeta potential of the CMP slurry of Reference Example. The decrease rate of the zeta potential was calculated by dividing the zeta potential decrease amount by the zeta potential of the CMP slurry of Reference Example. The results are shown in Table 1.

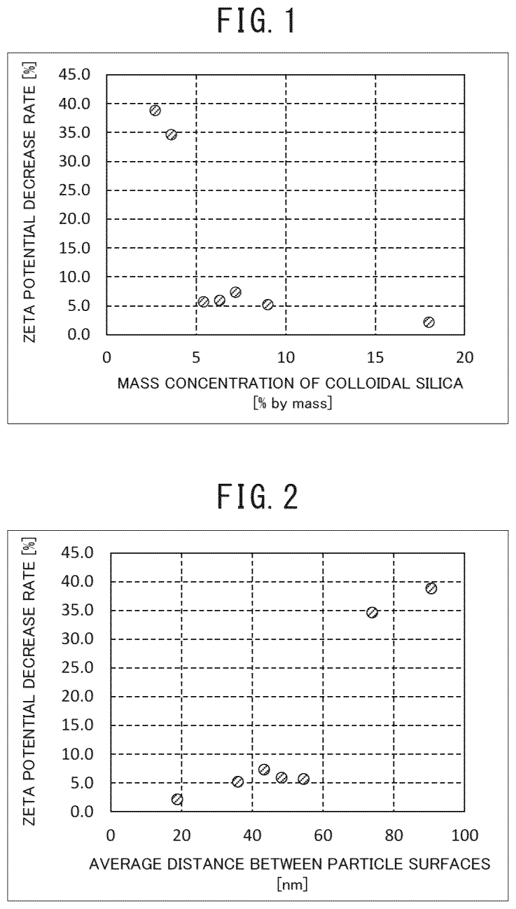

The correlation between the decrease rate of the zeta potential and the mass concentration [% by mass] of the colloidal silica is illustrated in FIG. 1. Further, the correlation between the decrease rate of the zeta potential and the average distance between particle surfaces [nm] of the colloidal silica is illustrated in FIG. 2.

### <Measurement of Polishing Removal Rate>

A silicon wafer with a silicon dioxide film (TEOS film) having a diameter of 300 mm was polished using the CMP slurry of each of Examples 1 to 5 and Comparative Examples 1, 2 under the following polishing conditions.
Polishing device: One side CMP polishing device for 300 mm wafer, FREX300E manufactured by EBARA CORPORATION
Polishing pad: Polyurethane pad IC1000 manufactured by Nitta Dupont Incorporated.
Polishing pressure: 3.0 psi (1 psi=6894.76 Pa)
Polishing platen rotation speed: 110 rpm.
Head rotation speed: 103 rpm.
Supply of CMP slurry: One-way
CMP slurry supply rate: 250 mL/min
Polishing time: 60 seconds

The silicon wafer was measured for each of the film thickness before the polishing and the film thickness after the polishing using an ellipsometric film thickness measurement system RE-3500 (SCREEN Semiconductor Solutions Co., Ltd.). Then, the polishing removal rate was calculated from the film thickness difference and the polishing time.

The increase amount of the TEOS film polishing removal rate was calculated by subtracting the polishing removal rate by the CMP slurry of Reference Example from the polishing removal rate by the CMP slurry of each of Examples 1 to 5 and Comparative Examples 1, 2. The increase rate of the polishing removal rate was calculated by dividing the increase amount of the polishing removal rate by the polishing removal rate of Reference Example. The results are shown in Table 1.

### Evaluation

As shown in Table 1, in the CMP slurry of each of Examples 1 to 5, the zeta potential was 30 mV or more, the decrease amount was 3 mV or less, and the decrease rate was 10% or less. On the other hand, in both of Comparative Examples 1, 2, the zeta potential was 25 mV or less, the decrease amount was more than 10 mV, and the decrease rate was more than 30%, which showed that the change amounts of the CMP slurries of Comparative Examples 1, 2, were larger than the change amounts of the CMP slurries of Examples.

In Examples 1 to 5, the polishing removal rate of the TEOS film was 76 Å/min or less, the increase amount was 5.5 Å/min or less, and the increase rate was 8% or less. On the other hand, in both of Comparative Examples 1, 2, the polishing removal rate of TEOS film was more than 76 Å/min, the increase amount was more than 5.5 Å/min, and the increase rate was more than 8%, which showed that the change amounts of Comparative Examples 1, 2 were larger than the change amounts of Examples.

These results showed that the changes with time in the zeta potential and the polishing performance are likely to decrease in the slurry composition having the mass concentration of the colloidal silica of 5% by mass or more as illustrated in FIG. 1 or the slurry composition having the average distance between particle surfaces of the colloidal silica of 65 nm or less as illustrated in FIG. 2.

The reasons for the decrease in changes with time in zeta potential and polishing performance are considered as follows. The fact that the mass concentration of the colloidal silica is 5% by mass or more or the fact that the average distance between particle surfaces of the colloidal silica is 65 nm or less means that the distance between the cationized colloidal silica particles is very short. In usual, the aminosilane coupling agent modified on the surface of the colloidal silica in the CMP slurry is unstable, and therefore is detached from the surface of the colloidal silica and diffused into the slurry with the passage of time. On the other hand, in the slurry composition according to the present invention, the average distance between particle surfaces of the cationized colloidal silica is very short, and therefore the aminosilane coupling agent is hardly detached from surface. Therefore, it is considered that the changes in physical properties and polishing performance decrease in the CMP slurry containing the slurry composition according to the present invention stored over a long period of time.

The present invention can also take the following configurations, for example.

[1]

A slurry composition containing: colloidal silica; and an acidic compound, in which
the pH is less than 7
the colloidal silica has a surface modified by an aminosilane coupling agent, and
when the average secondary particle diameter of the colloidal silica is set to dₚ [mm], the ratio of the volume of the colloidal silica to the volume of the slurry composition is set to F, and the ratio of circumference of circle to its diameter is set to π, the average distance between particle surfaces h of the colloidal silica represented by Equation (1) is less than 65 nm.

$$[ Math . 7 ]$$

$$h = {d}_{p} \{ \sqrt{( \frac{1}{3 π F} + \frac{5}{6} )} - 1 \} \qquad ( 1 )$$

[2]

The slurry composition according to [1], in which the slurry composition is a CMP slurry for storage.

[3]

The slurry composition according to [1] or [2], in which the pH is less than 5.

[4] The slurry composition according to any one of [1] to [3], in which the average secondary particle diameter of the colloidal silica is less than 90 nm.
[5]

The slurry composition according to any one of [1] to [4], in which the aminosilane coupling agent is at least one selected from the group consisting of bis(2-hydroxyethyl)-3-aminopropyltrialkoxysilane, diethylaminomethyltrialkoxysilane, (N,N-diethyl-3-aminopropyl)trialkoxysilane, 3-(N-styrylmethyl-2-aminoethylamino)propyltrialkoxysilane, aminopropyltrialkoxysilane, trialkoxysilylpropyl-N,N,N-trimethylammonium, bis(methyldialkoxysilylpropyl)-N-methylamine, bis(trialkoxysilylpropyl)urea, bis(3-(trialkoxysilyl)propyl)-ethylenediamine, bis(trialkoxysilylpropyl)amine, 3-aminopropyltrialkoxysilane, N-(2-aminoethyl)-3-aminopropylmethyldialkoxysilane, N-(2-aminoethyl)-3-aminopropyltrialkoxysilane, 3-aminopropylmethyldialkoxysilane, 3-aminopropyltrialkoxysilane, (N-trialkoxysilylpropyl) polyethyleneimine, trialkoxysilylpropyldiethylenetriamine, N-phenyl-3-aminopropyltrialkoxysilane, and 4-aminobutyltrialkoxysilane.

[6]

A method for storing a slurry composition including:
preparing a slurry composition containing colloidal silica having a surface modified by an aminosilane coupling agent and an acidic compound and having a pH of less than 7 such that, when the average secondary particle diameter of the colloidal silica is set to dₚ [nm], the ratio of the volume of the colloidal silica to the volume of the slurry composition is set to F, and the ratio of circumference of circle to its diameter is set to π, the average distance between particle surfaces h of the colloidal silica represented by Equation (1) is less than 65 nm; and
storing the prepared slurry composition.

$$[ Math . 8 ]$$

$$h = {d}_{p} \{ \sqrt{( \frac{1}{3 π F} + \frac{5}{6} )} - 1 \} \qquad ( 1 )$$

[7]

The method for storing a slurry composition according to [6], including: setting the mass concentration of the colloidal silica contained in the slurry composition to 5% by mass or more.

[8]

The method for storing a slurry composition according to [6] or [7], in which the average secondary particle diameter of the colloidal silica is less than 90 nm.

[9]

The method for storing a slurry composition according to any one of [6] to [8], in which the aminosilane coupling agent is at least one selected from the group consisting of bis(2-hydroxyethyl)-3-aminopropyltrialkoxysilane, diethylaminomethyltrialkoxysilane, (N,N-diethyl-3-aminopropyl)trialkoxysilane, 3-(N-styrylmethyl-2-aminoethylamino)propyltrialkoxysilane, aminopropyltrialkoxysilane, trialkoxysilylpropyl-N,N,N-trimethylammonium, bis(methyldialkoxysilylpropyl)-N-methylamine, bis(trialkoxysilylpropyl)urea, bis(3-(trialkoxysilyl)propyl)-ethylenediamine, bis(trialkoxysilylpropyl)amine, 3-aminopropyltrialkoxysilane, N-(2-aminoethyl)-3-aminopropylmethyldialkoxysilane, N-(2-aminoethyl)-3-aminopropyltrialkoxysilane, 3-aminopropylmethyldialkoxysilane, 3-aminopropyltrialkoxysilane, (N-trialkoxysilylpropyl) polyethyleneimine, trialkoxysilylpropyldiethylenetriamine, N-phenyl-3-aminopropyltrialkoxysilane, and 4-aminobutyltrialkoxysilane.

[10]

A method for producing a CMP slurry, the CMP slurry being a CMP slurry used in performing chemical mechanical polishing, including:
preparing a slurry composition containing colloidal silica having a surface modified by an aminosilane coupling agent and an acidic compound and having a pH of less than 7 such that, when the average secondary particle diameter of the colloidal silica is set to dₚ [nm], the ratio of the volume of the colloidal silica to the volume of the slurry composition is set to F, and the ratio of circumference of circle to its diameter is set to π, the average distance between particle surfaces h of the colloidal silica represented by Equation (1) is less than 65 nm;
storing the prepared slurry composition; and
diluting the stored slurry composition with a liquid medium to obtain a CMP slurry,

$$[ Math . 9 ]$$

$$h = {d}_{p} \{ \sqrt{( \frac{1}{3 π F} + \frac{5}{6} )} - 1 \} . \qquad ( 1 )$$

[11]

A polishing method including:
diluting the slurry composition according to any one of [1] to [5] with a liquid medium to obtain a CMP slurry; and
polishing an object to be polished provided on a substrate using the obtained CMP slurry.

1. A slurry composition comprising:
colloidal silica; and
an acidic compound, wherein
a pH is less than 7,
the colloidal silica has a surface modified by an aminosilane coupling agent, and
when an average secondary particle diameter of the colloidal silica is set to dₚ [mm], a ratio of a volume of the colloidal silica to a volume of the slurry composition is set to F, and a ratio of circumference of circle to its diameter is set to π, an average distance between particle surfaces h of the colloidal silica represented by Equation (1) is less than 65 nm,
$$[ Math . 1 ]$$
$$h = {d}_{p} \{ \sqrt{( \frac{1}{3 π F} + \frac{5}{6} )} - 1 \} . \qquad ( 1 )$$

2. The slurry composition according to claim 1, wherein the slurry composition is a CMP slurry for storage.

3. The slurry composition according to claim 1, wherein the pH is less than 5.

4. The slurry composition according to claim 1, wherein the average secondary particle diameter of the colloidal silica is less than 90 nm.

5. The slurry composition according to claim 1, wherein
the aminosilane coupling agent is at least one selected from the group consisting of bis(2-hydroxyethyl)-3-aminopropyltrialkoxysilane, diethylaminomethyltrialkoxysilane, (N,N-diethyl-3-aminopropyl)trialkoxysilane, 3-(N-styrylmethyl-2-aminoethylamino)propyltrialkoxysilane, aminopropyltrialkoxysilane, trialkoxysilylpropyl-N,N,N-trimethylammonium, bis(methyldialkoxysilylpropyl)-N-methylamine, bis(trialkoxysilylpropyl)urea, bis(3-(trialkoxysilyl)propyl)-ethylenediamine, bis(trialkoxysilylpropyl)amine, 3-aminopropyltrialkoxysilane, N-(2-aminoethyl)-3-aminopropylmethyldialkoxysilane, N-(2-aminoethyl)-3-aminopropyltrialkoxysilane, 3-aminopropylmethyldialkoxysilane, 3-aminopropyltrialkoxysilane, (N-trialkoxysilylpropyl) polyethyleneimine, trialkoxysilylpropyldiethylenetriamine, N-phenyl-3-aminopropyltrialkoxysilane, and 4-aminobutyltrialkoxysilane.

6. A method for storing a slurry composition comprising:
preparing a slurry composition containing colloidal silica having a surface modified by an aminosilane coupling agent and an acidic compound and having a pH of less than 7 such that, when an average secondary particle diameter of the colloidal silica is set to dₚ [mm], a ratio of a volume of the colloidal silica to a volume of the slurry composition is set to F, and a ratio of circumference of circle to its diameter is set to π, an average distance between particle surfaces h of the colloidal silica represented by Equation (1) is less than 65 nm; and
storing the prepared slurry composition,
$$[ Math . 2 ]$$
$$h = {d}_{p} \{ \sqrt{( \frac{1}{3 π F} + \frac{5}{6} )} - 1 \} . \qquad ( 1 )$$

7. The method for storing a slurry composition according to claim 6 comprising:
setting a mass concentration of the colloidal silica contained in the slurry composition to 5% by mass or more.

8. The method for storing a slurry composition according to claim 6, wherein the average secondary particle diameter of the colloidal silica is less than 90 nm.

9. The method for storing a slurry composition according to claim 6, wherein
the aminosilane coupling agent is at least one selected from the group consisting of bis(2-hydroxyethyl)-3-aminopropyltrialkoxysilane, diethylaminomethyltrialkoxysilane, (N,N-diethyl-3-aminopropyl)trialkoxysilane, 3-(N-styrylmethyl-2-aminoethylamino)propyltrialkoxysilane, aminopropyltrialkoxysilane, trialkoxysilylpropyl-N,N,N-trimethylammonium, bis(methyldialkoxysilylpropyl)-N-methylamine, bis(trialkoxysilylpropyl)urea, bis(3-(trialkoxysilyl)propyl)-ethylenediamine, bis(trialkoxysilylpropyl)amine, 3-aminopropyltrialkoxysilane, N-(2-aminoethyl)-3-aminopropylmethyldialkoxysilane, N-(2-aminoethyl)-3-aminopropyltrialkoxysilane, 3-aminopropylmethyldialkoxysilane, 3-aminopropyltrialkoxysilane, (N-trialkoxysilylpropyl) polyethyleneimine, trialkoxysilylpropyldiethylenetriamine, N-phenyl-3-aminopropyltrialkoxysilane, and 4-aminobutyltrialkoxysilane.

10. A method for producing a CMP slurry,
the CMP slurry being a CMP slurry used in performing chemical mechanical polishing,
comprising:
preparing a slurry composition containing colloidal silica having a surface modified by an aminosilane coupling agent and an acidic compound and having a pH of less than 7 such that, when an average secondary particle diameter of the colloidal silica is set to dₚ [mm], a ratio of a volume of the colloidal silica to a volume of the slurry composition is set to F, and a ratio of circumference of circle to its diameter is set to π, an average distance between particle surfaces h of the colloidal silica represented by Equation (1) is less than 65 nm;
storing the prepared slurry composition; and
diluting the stored slurry composition with a liquid medium to obtain a CMP slurry,
$$[ Math . 3 ]$$
$$h = {d}_{p} \{ \sqrt{( \frac{1}{3 π F} + \frac{5}{6} )} - 1 \} . \qquad ( 1 )$$

11. A polishing method comprising:
diluting the slurry composition according to claim 1 with a liquid medium to obtain a CMP slurry; and
polishing an object to be polished provided on a substrate using the obtained CMP slurry.

12. The slurry composition according to claim 2, wherein a pH is less than 5.

13. The slurry composition according to claim 2, wherein the average secondary particle diameter of a colloidal silica is less than 90 nm.

14. The slurry composition according to claim 2, wherein
the aminosilane coupling agent is at least one selected from the group consisting of bis(2-hydroxyethyl)-3-aminopropyltrialkoxysilane, diethylaminomethyltrialkoxysilane, (N,N-diethyl-3-aminopropyl)trialkoxysilane, 3-(N-styrylmethyl-2-aminoethylamino)propyltrialkoxysilane, aminopropyltrialkoxysilane, trialkoxysilylpropyl-N,N,N-trimethylammonium, bis(methyldialkoxysilylpropyl)-N-methylamine, bis(trialkoxysilylpropyl)urea, bis(3-(trialkoxysilyl)propyl)-ethylenediamine, bis(trialkoxysilylpropyl)amine, 3-aminopropyltrialkoxysilane, N-(2-aminoethyl)-3-aminopropylmethyldialkoxysilane, N-(2-aminoethyl)-3-aminopropyltrialkoxysilane, 3-aminopropylmethyldialkoxysilane, 3-aminopropyltrialkoxysilane, (N-trialkoxysilylpropyl) polyethyleneimine, trialkoxysilylpropyldiethylenetriamine, N-phenyl-3-aminopropyltrialkoxysilane, and 4-aminobutyltrialkoxysilane.

15. The method for storing a slurry composition according to claim 7, wherein the average secondary particle diameter of the colloidal silica is less than 90 nm.

16. The method for storing a slurry composition according to claim 7, wherein
the aminosilane coupling agent is at least one selected from the group consisting of bis(2-hydroxyethyl)-3-aminopropyltrialkoxysilane, diethylaminomethyltrialkoxysilane, (N,N-diethyl-3-aminopropyl)trialkoxysilane, 3-(N-styrylmethyl-2-aminoethylamino)propyltrialkoxysilane, aminopropyltrialkoxysilane, trialkoxysilylpropyl-N,N,N-trimethylammonium, bis(methyldialkoxysilylpropyl)-N-methylamine, bis(trialkoxysilylpropyl)urea, bis(3-(trialkoxysilyl)propyl)-ethylenediamine, bis(trialkoxysilylpropyl)amine, 3-aminopropyltrialkoxysilane, N-(2-aminoethyl)-3-aminopropylmethyldialkoxysilane, N-(2-aminoethyl)-3-aminopropyltrialkoxysilane, 3-aminopropylmethyldialkoxysilane, 3-aminopropyltrialkoxysilane, (N-trialkoxysilylpropyl) polyethyleneimine, trialkoxysilylpropyldiethylenetriamine, N-phenyl-3-aminopropyltrialkoxysilane, and 4-aminobutyltrialkoxysilane.
